(19) United States
(12) Patent Application Publication
(10) Pub. No.: US 2025/0230993 A1
(43) Pub. Date: Jul. 17, 2025

(54) COOLING DEVICE

(71) Applicant: Miba Sinter Austria GmbH, Laakirchen (AT)

(72) Inventors: Manuel POHN, Zell am Pettenfirst (AT); Jürgen WINDHAGER, Losenstein (AT)

(73) Assignee: Miba Sinter Austria GmbH, Laakirchen (AT)

(21) Appl. No.: 18/991,900

(22) Filed: Dec. 23, 2024

(30) Foreign Application Priority Data
Jan. 16, 2024 (AT) A50022/2024

(51) Int. Cl. F28F 3/02

(52) U.S. Cl. CPC F28F 3/022; F28F 3/025; F28F 2215/00; F28F 2255/18

(57) ABSTRACT

A cooling device for cooling components includes a base element with a first surface, and with a cooling structure having cooling elements that is arranged on the base element so as to protrude over the first surface. The cooling elements are made of a sinter material and are produced by forming from the material of the base element. The base element has a maximum element height of 3 mm, in particular between 1 mm and 2.5 mm.

### CROSS REFERENCE TO RELATED APPLICATIONS

Applicant claims priority under 35 U.S.C. § 119 of Austrian Application No. A50022/2024 filed Jan. 16, 2024, the disclosure of which is incorporated by reference.

### BACKGROUND OF THE INVENTION

### 1. Field of the Invention

The invention relates to a cooling device for cooling components comprising a base element with a first surface, and with a cooling structure having cooling elements which is arranged on the base element so as to protrude over the first surface.

The invention also relates to a method for producing a cooling device comprising the steps of providing a material and configuring a cooling structure from the material.

### 2. Description of the Related Art

So-called power electronics components, such as power semiconductors, are well known from the state of the art. Such components are frequently used, for example in motor vehicles. It is also known that these components generate large amounts of heat during operation, which often needs to be dissipated using a cooling medium. A wide variety of coolers are known in the prior art for this purpose, including so-called pin fin heat sinks, which are surrounded by a cooling medium and thus transfer the heat from the pins to the cooling medium. DE 10 2019 108 106 A1 describes for example a cooler for a power semiconductor in an inverter, wherein the cooler is configured in two parts and comprises a base plate as a first part, which can be connected to the power semiconductor in a thermally conductive manner; a heat sink as a second part, which is arranged on the base plate, wherein the heat sink has at least one wave-shaped recess, which is formed continuously from a side of the heat sink facing away from the base plate to a side facing the heat sink; wherein the first and second parts are connected to one another and are coated with a layer, which protects both parts from electrochemical reduction.

DE 10 2018 216 859 A1 discloses a device for cooling components, including a first and a second base body; cylindrical and/or conical first cooling fins which are configured in the first base body and around which a coolant can flow, and cylindrical and/or conical second cooling fins which are configured in the second base body and around which the coolant can flow, the second base body being joined to the first base body in such a way that the second cooling fins come to lie between the first cooling fins without touching the first base body.

### SUMMARY OF THE INVENTION

The present invention is based on the object of providing a cooling device for components with an enhanced cooling performance.

The object of the invention is solved in the cooling device mentioned at the beginning in that the base element has a maximum element thickness of 3 mm, in particular between 1 mm and 2.5 mm.

Furthermore, the object of the invention is solved by the method mentioned at the beginning, according to which a sintering powder is used as the material, from which a green compact is produced by pressing, the green compact is sintered to form a preform, and the cooling structure in the form of cooling elements is produced from the preform by forming, for which purpose a part of the preform is pressed through a mold, a base element being formed from the preform, on which the cooling elements are formed, and wherein the base element is produced with a maximum element thickness of 3 mm, in particular between 1 mm and 2.5 mm.

The advantage of this is that the thin element thickness (also referred to as element height) of the base element compared to known cooling devices means that heat exchange can be increased due to a lower thermal resistance. Such a thin plate thickness cannot be produced with conventional technologies, or only at great expense, as conventional technologies use machining processes. For machining, however, the cooling plates must have a certain minimum thickness in order to be clamped. On the other hand, the materials used in conventional methods have a higher stiffness compared to sintered materials of the same composition, which counteracts forming. These limitations can be avoided with the method according to the invention, which means that cooling devices with a thin element thickness of the base element can also be produced. The advantage here is that the forming of the base element to the cooling elements means that no waste material is produced for their production, as is the case with machining, for example. In addition, all cooling elements of the cooling device can be produced at the same time, which may lead to a corresponding increase in productivity.

According to an embodiment variant of the invention, at least one stiffening element may be arranged to increase the flexural strength of the base element. This is preferably arranged on the first surface of the base element, on which the cooling elements are also located. This may achieve the additional effect that the stiffening element can further improve the cooling performance of the cooling device.

Preferably, according to an embodiment variant of the invention, the at least one stiffening element is provided with a rib-shaped configuration, so that the coolant flowing around the cooling elements can flow better over the stiffening element.

In order to enable a cooling structure from the cooling elements that is as unimpaired as possible, according to a further embodiment variant of the invention, it may be provided that the stiffening element is arranged continuously around the circumference of the base element. The continuous arrangement may also lead to turbulence in the cooling fluid, which may improve the cooling performance of the cooling device.

According to a further embodiment variant of the invention, it may also be provided that the stiffening element is arranged between the cooling elements, wherein the proportion of heat dissipated via the stiffening element may be increased.

In order to influence the flow behavior of the cooling fluid flowing between the cooling elements and thus also to influence the heat dissipation, according to an embodiment variant of the invention it may be provided that the stiffening element has a wave-shaped configuration.

According to an embodiment variant, several wave-shaped stiffening elements may form the cooling elements, which may simplify the production of the cooling device.

According to a further embodiment variant of the invention, it may be provided that the stiffening element has a height which corresponds to between 20% and 100% of a maximum height in the same direction of the cooling elements. This may simplify the configuration of the cooling elements or any further non-machining processing that may be required, such as compression.

Like the cooling elements, the at least one stiffening element according to an embodiment variant of the invention also preferably consists of a sinter material and is produced by forming from the material of the base element, in particular according to an embodiment variant of the method with forming the preform on the base element. The advantages mentioned for the cooling elements may thus be achieved.

To improve the flow behavior of the cooling device and thus for improved heat dissipation, according to an embodiment variant of the invention it may be provided that the stiffening element is arranged with a longitudinal extension in the direction of flow for a cooling fluid through the cooling device.

### BRIEF DESCRIPTION OF THE DRAWINGS

Other objects and features of the invention will become apparent from the following detailed description considered in connection with the accompanying drawings. It is to be understood, however, that the drawings are designed as an illustration only and not as a definition of the limits of the invention.

In the drawings,

FIG. 1 shows a side view of a cooling device with a component to be cooled;

FIG. 2 shows an oblique view of a cooling device;

FIG. 3 shows a side view of an embodiment variant of a cooling device;

FIG. 4 shows a top view of a section of a further embodiment variant of a cooling device;

FIG. 5 shows a top view of a section of a further embodiment variant of a cooling device;

FIG. 6 shows an embodiment variant of a preform; and

FIG. 7 shows an embodiment variant of a tool for producing the cooling device.

### DETAILED DESCRIPTION OF PREFERRED EMBODIMENTS

By way of introduction, it should be noted that in the various embodiments described, the same parts are provided with the same reference signs or the same component designations, wherein the disclosures contained in the entire description can be transferred analogously to the same parts with the same reference signs or the same component designations. Moreover, the specifications of location, such as at the top, at the bottom, at the side, chosen in the description refer to the directly described and depicted figure and in case of a change of position, these specifications of location are to be analogously transferred to the new position.

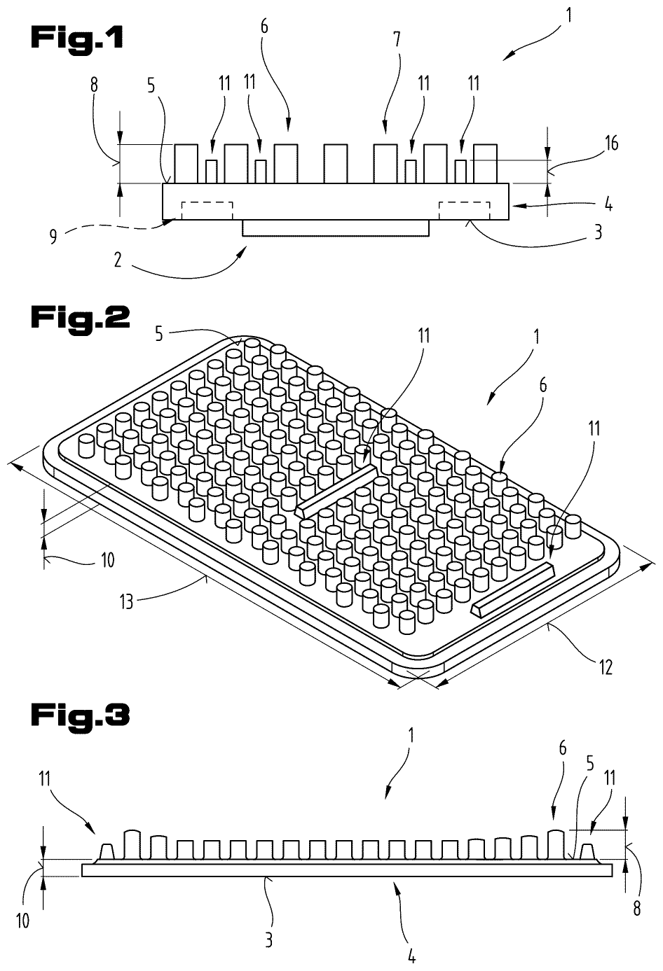

FIG. 1 shows a side view of a cooling device 1.

The cooling device 1 is used to cool a component 2 or several components 2 or an assembly. For this purpose, the cooling device 1 abuts with a rear side 3 against the at least one component 2, in particular directly, and is therefore preferably in direct contact with the component 2 for heat exchange.

The component 2 is preferably an electronic component, in particular a so-called power electronics component or high-performance electronics component or a power semiconductor or high-performance semiconductor. In particular, such components 2 or assemblies made of/with these components 2 may be designed for a power output in the range from several kW up to MW. Such components 2 are used, for example, to convert electrical energy with switching electronic components. Typical applications include converters or frequency converters in the field of electrical drive technology, solar inverters and converters for wind turbines for feeding regeneratively generated energy into the grid or switching power supplies, generally the conversion of AC voltage into DC voltage by rectifiers, the conversion of DC voltage into AC voltage by inverters, control systems, for example in the drive technology of an electric drive in electric vehicles or hybrid vehicles, battery management systems, etc. A power electronics component may, for example, be a semiconductor, in particular a so-called power semiconductor, e.g. an insulated-gate bipolar transistor (IGBT).

Since such components 2 are known in the prior art, reference is made to this prior art in order to avoid repetition of further details.

The cooling device 1 comprises a base element 4, which also forms the rear side 3 of the cooling device 1, and which has a cooling structure on a first surface 5, or consists of the base element 4 and the cooling structure. The cooling structure is formed by cooling elements 6, which are arranged projecting over the first surface 5 on the base element 4 and are integrally connected to it, as may also be seen in FIG. 2. In other words, in the preferred embodiment variant, the cooling device 1 is formed by only one single piece. Irrespective of this one-piece nature, it is possible within the scope of the invention that several cooling devices 1 may be combined with one another per component 2 or assembly of/with at least one such component 2 to form a cooling device group according to the invention. In particular, cooling devices 1 may therefore also be assembled in a modular way to form a cooling device group.

The base element 4 and the cooling elements 6 are made of or consist of a sinter material. Furthermore, the cooling elements 6 are produced by forming from the base element 4 or a preform.

In the preferred embodiment variant, the base element 4 and the cooling elements 6 have a density of at least 98%, in particular at least 98.5%, preferably at least 99%, of the full density of the material used.

The full density refers to the density of a cooling device made from the same material using melting metallurgy, i.e. a component made from a solid material. The term “solid material” refers to a metallic material that, with the exception of imperfections, has no pores, as is usually the case with sintered components.

The cooling elements 6 are designed to be surrounded by a cooling fluid, for example water, so that the heat absorbed by the cooling device 1 is removed via this cooling fluid. Preferably, the cooling device 1 is a so-called pin fin cooling device.

The cooling elements 6 of the embodiment variant shown are cylindrical. However, they may also have a different shape, for example a truncated cone or mushroom shape, or generally one with a cross-section that expands or tapers in the direction of a cooling element head 7, for example a truncated pyramid shape.

The cross-section of the cooling elements 6 may be circular, oval, diamond-shaped, square, etc.

Furthermore, all cooling elements 6 may have the same configuration. However, it is also possible to arrange or combine cooling elements 6 with different shapes on a base element 4.

The cooling elements 6 may preferably have a height 8 above the first surface 5 of the base element 4, which is between 2 mm and 20 mm.

In the simplest embodiment of the cooling device 1, all cooling elements 6 of the cooling device 1 have the same height 8 within the tolerances. However, it is conceivable within the scope of the invention, as shown as an example in FIG. 3, for some of the cooling elements 6 to have a lower height than the rest of the cooling elements 6. For example, cooling elements 6 at the edges may be higher than the rest or the cooling elements 6 may have a progression of heights 8 from lower or higher in the center of the cooling device 1 to higher or lower at the edge of the cooling device 1. Other embodiments of different heights 8 are possible within the scope of the invention.

Furthermore, it may be provided that between 300 and 1300, in particular between 300 and 1000, for example between 300 and 750, cooling elements 6 are arranged or configured per dm² of the first surface. In particular, this number has proven to be advantageous with regard to the production of the cooling device 1, i.e. the forming of the base element 4 or a preform to the cooling elements 6, as damage to the cooling elements 6 or incompletely formed cooling elements 6 may thus be avoided or reduced.

As may be seen in particular from FIG. 1, according to one embodiment variant of the cooling device 1, it may be provided that the rear side 3 of the base element 4 is configured with a flat surface. However, it is also conceivable that the rear side 3 is configured with one or more depressions 9, in which a component 2 is at least partially accommodated. This enables a better connection of the component 2 to the cooling device 1. In general, the component 2 may be glued or screwed or soldered or sintered, etc., to the cooling device 1.

The at least one depression 9 may be produced at the same time as the cooling elements 6. The at least one depression 9 also makes it possible to produce cooling elements 6 whose height 8 is greater than that of the rest of the cooling elements 6.

It is provided that the base element 4 has a maximum element height 10 of 3 mm. In particular, the base element 4 may have an element height 10 of between 1 mm and 2.5 mm. The element height 10 of the (plate-shaped) base element 4 is measured between its rear side 3 and the first surface 5. If a depression 9 is provided in the rear side 3, the element height 10 is measured next to the depression 9.

As may be seen from FIG. 2, the cooling device 1 may have at least one stiffening element 11 on the first surface 5 of the base element 4. The stiffening element 11 has a rib-shaped configuration in the embodiment shown, but may also have a different shape.

It is also conceivable that the at least one stiffening element 11 or a stiffening element 11 is arranged on the rear side 3 of the base element 4, in particular if the cooling device 1 has a larger surface area than the component 2, so that even in this case the component 2 can come into abutment with the cooling device 1 over a large area. For example, in this embodiment variant, the component 2 may be arranged between the stiffening elements 11.

It is also conceivable that the at least one stiffening element 11 terminates flush with the rear side 3 or the first surface 5 and is made of a different, stiffer material than the rest of the base element 4.

In FIG. 2, two stiffening elements 11 are shown as an example, one extending at the edge of the base element 4 over a portion of a width 12 of the base element 4 and the second being arranged centrally on the base element 4. These arrangements are to be understood as exemplary embodiments only. On the one hand, only a single stiffening element 11 or more than two stiffening elements 11, for example three or four or five or six, may be provided. On the other hand, stiffening elements 11 of the same or different shape and/or length and/or size or configuration (on the first surface 5) may also be provided. For example, a stiffening element 11 may extend continuously over at least 80%, in particular at least 90%, for example between 90% and 98%, of the width 12 of the base element 4. The same applies to a length 13 of the base element 4.

In the preferred embodiment variant, the stiffening element 11 or the stiffening elements 11 are arranged exclusively on the first surface 5 of the base element 4.

If only one stiffening element 11 is discussed in the following, then these embodiments may also be applied to several or all stiffening elements 11 that are arranged on the first surface 5 of the base element 4 or on the base element 4 if several stiffening elements 11 are provided.

The stiffening element 11 may, for example, have a triangular, rectangular or trapezoidal cross-sectional shape, although other cross-sectional shapes are also conceivable.

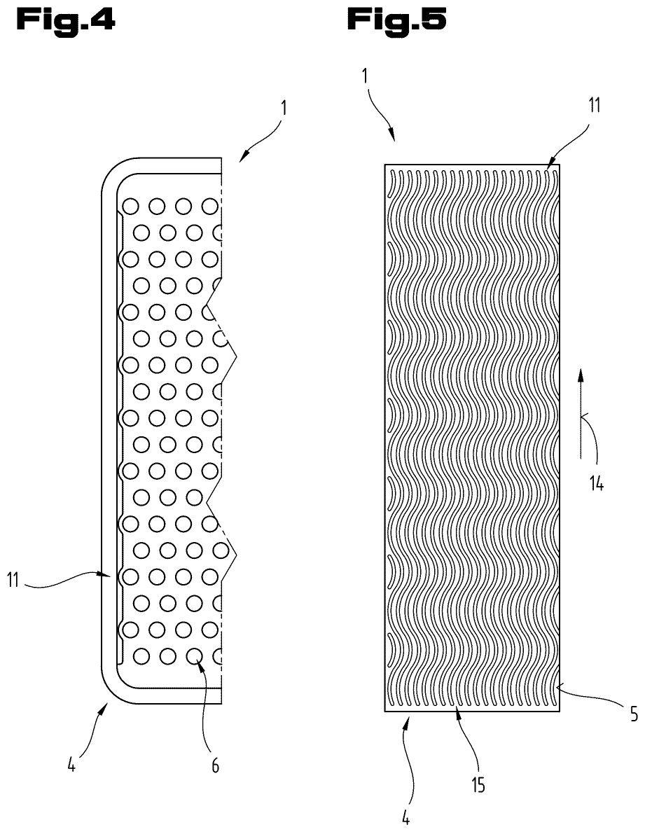

In the embodiment variant shown in FIG. 3, a stiffening element 11 is provided between the end faces and the cooling elements 6 along the wide sides of the base element 4. FIG. 4 shows a section of an embodiment variant of the cooling device 1 in which the stiffening element 11 is arranged continuously around the circumference of the base element 4. As may also be seen from this FIG. 4, the stiffening element 11 may be arranged directly at the edge of the base element 4. FIGS. 2 and 3 show that the stiffening element 11 may also be arranged at a distance from the edge of the base element 4.

Furthermore, the stiffening element 11 is rounded in the corner areas of the base element 4 as shown in FIG. 4. However, it may also be configured differently, for example with an inclined course towards the edge or following the corners of the base element 4.

In FIG. 4, the stiffening element 11 is arranged between the edge and the cooling elements 6. As may be seen from FIG. 1, the stiffening element 11 or stiffening elements 11 may also be arranged between the cooling elements 6, for example also exclusively between the cooling elements 6. With regard to the stiffening elements 11, however, a combination of the embodiment variants according to FIGS. 1 and 4 is also conceivable, so that stiffening elements 11 may be arranged along the edge of the base element 4 and between the cooling elements 6.

The stiffening element 11 may have a rectilinear course, as shown in FIG. 2, for example, or, according to an embodiment variant, a non-rectilinear course, in particular a wave-shaped one, as shown in the section of the cooling device 1 in FIG. 5. These wave-shaped stiffening elements 11 may also be arranged in a course between the cooling elements 6. However, in the embodiment variant shown in FIG. 5, the wave-shaped stiffening elements 11 also form the cooling elements 6 of the cooling device 1. According to a further embodiment variant, it may also be provided that the stiffening elements 11 are arranged with a longitudinal extension at least approximately in a flow direction 14 for a cooling fluid through the cooling device 1. This may also be provided in other embodiment variants of the cooling device 1 and is therefore not limited to the embodiment variant shown in FIG. 5. In the embodiment variant shown in FIG. 5, channels 15 for the cooling fluid are configured between the stiffening elements 11.

Preferably, the stiffening elements 11 are lower than the cooling elements 6, especially if they do not also form the cooling elements 6. According to a further embodiment variant, it may be provided that the stiffening element 11 has a height 16 that corresponds to between 20 and 100%, in particular 60 and 90%, of the height 8 or, in the case of cooling elements 6 of different heights, the maximum height 8 in the same direction of the cooling elements 6.

A width of the stiffening element 11 (parallel to the first surface 5 of the base element 4) may be between 0.5 mm and 4 mm.

In principle, the stiffening element 11 may be subsequently attached to the base element 4, for example after the cooling elements 6 have been formed. According to an embodiment variant, however, the stiffening element 11 may be pressed or produced by powder metallurgy from the sintered material during the pressing of a preform for the manufacture of the cooling device 1. According to a further embodiment variant, the stiffening element 11 may be produced from the sintered material by forming from the material of the base element 4, preferably at the same time as the cooling elements 6 are produced from the preform.

The stiffening element 11 or the stiffening elements 11 are therefore preferably configured in one piece with the base element 4 and the cooling elements 6. It is further preferred if the stiffening element 11 or the stiffening elements 11 are produced in net shape or near net shape quality.

A sintering powder or a powder used in powder metallurgy, in particular a metallic powder, is used to produce the cooling device 1. Preferably, a sintering powder is used that has a correspondingly good thermal conductivity. In particular, a sintering powder based on aluminum or an aluminum alloy or based on copper or a copper alloy or a MMC (metal matrix composite) sintering powder is used.

The cooling device 1 is produced by powder metallurgy using a powder metallurgy method, so it is preferred that it is a sintered component. For this purpose, a green compact is produced in a corresponding press mold (die) from a powder, which may be produced from the individual (metallic) powders by mixing, wherein the powders may be used pre-alloyed if necessary. Preferably, the green compact has a density of at least 80%, in particular between 80% and 96%, of the full density of the material.

The green compact is then dewaxed at normal temperatures and sintered in one or two stages or in several stages and then cooled, preferably to room temperature. Sintering may take place at a temperature between 500° C. and 1300° C., for example.

Since these methods and the method parameters used are also known from the prior art, reference is made to the relevant prior art in order to avoid repetition.

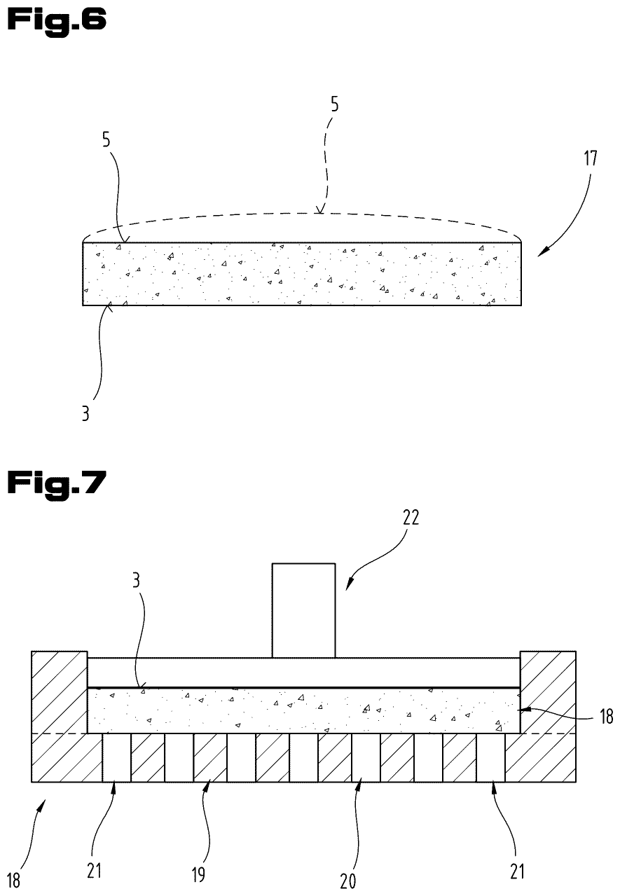

Sintering produces a preform 17 from the green compact, as shown as an example in FIG. 6. The preform 17 may be configured as a flat plate, so that the rear side 3 and the first surface 5 may run parallel to each other.

According to an embodiment variant, it may be provided that the first surface 5 of the preform 17, on which the cooling structure and in particular at least one stiffening element 11 is configured, is produced curved, at least in portions. Other shapes of the first surface 5 of the preform 17 are possible with regard to improved formability of the preform 17. This means that the first pin fin projections or cooling element projections (circular, oval, elliptical, etc.) with a height of between 0.1 mm and 2.0 mm may already be preformed. It may also be possible to provide lugs of at least one stiffening element 11. In addition, structures (waves, ribs, etc.) may be deliberately introduced into the first surface 5 of the preform 17 in order to increase the turbulence of a cooling fluid if necessary.

The preform 17 may subsequently be recompressed. The recompression may take place simultaneously with the forming of the preform 17 to the cooling elements 6 and the stiffening element(s) 11.

The forming of the preform 17 is realized in a mold 18. For this purpose, the preform 17 is inserted into or placed against the mold 18. In the simplest case, the mold 18 for producing the cooling elements 6 is formed by a perforated plate 19. The perforated plate 19 has recesses 20, in particular apertures, into or through which some of the material of the preform 17 is pressed, forming the cooling elements 6. To form the stiffening element 11 or stiffening elements 11, corresponding elongated or wave-shaped recesses 21 or apertures may be provided in the perforated plate 19, depending on their shape.

The rest of the material of the preform 17, which is not pressed into or through the mold 18, forms the base element 4. The later desired element height 10 of the base element 4 of a maximum of 3 mm is already taken into account on the preform 17 depending on the forming to be carried out to form the cooling elements 6 and the stiffening element 11 or stiffening elements 11.

The recesses 20, 21, i.e. their cross-section, are adapted accordingly to the cross-section of the cooling elements 6 or stiffening elements 11 to be produced.

The mold 18 may also look different, so it does not necessarily have to be a perforated plate 19. In particular, the mold 18 may have a “pot-shaped” configuration as a die.

For forming, a punch 22 is applied to the rear side 3 of the preform 17, which also forms the rear side 3 of the base element 4, and pressed onto the preform 17 with a predeterminable pressure. For example, forming may take place at a pressure of between 700 MPa and 1600 MPa. Furthermore, forming may take place during a time of up to 10 seconds, in particular between 0.1 seconds and 10 seconds. Furthermore, the forming preferably takes place at room temperature (20° C.), i.e. cold, or the forming may also take place after preheating the preform 17 to a temperature between 50° C. and 300° C., for example between 50° C. and 150° C., and/or in/with a mold 18 heated to a temperature between 50° C. and 300° C., for example between 50° C. and 150° C.

After the shaping, i.e. the forming of the preform 17, the cooling device 1 may be finished. However, it is also possible to post-process the cooling device 1. For example, the cooling elements 6 and/or the stiffening element(s) 11 may be recompressed at least in certain portions, for example in the free ends.

The preform 17 may be formed in one or more stages, so that the cooling elements 6 and/or the stiffening element(s) 11 can be formed in one or more stages.

It is also possible for the cooling elements 6 and/or the stiffening element(s) 11 to be provided with a coating, in particular a corrosion-resistant coating.

The exemplary embodiments show possible embodiment variants, wherein it should be noted at this point that combinations of the individual embodiment variants with one another are also possible.

Finally, for the sake of order, it should be noted that for a better understanding of the structure of the cooling device 1 or the mold 12, these are not necessarily shown to scale.

Although only a few embodiments of the present invention have been shown and described, it is to be understood that many changes and modifications may be made thereunto without departing from the spirit and scope of the invention.

### REFERENCE SIGNS LIST

1 cooling device
2 component
3 rear side
4 base member
5 surface
6 cooling element
7 cooling element head
8 height
9 depression
10 element height
11 stiffening element
12 width
13 length
14 flow direction
15 channel
16 height
17 preform
18 mold
19 perforated plate
20 recess
21 recess
22 punch

What is claimed is:

1. A cooling device (1) for cooling components (2), comprising a base element (4) having a first surface (5), and having a cooling structure which has cooling elements (6) and is arranged on the base element (4) so as to project beyond the first surface (5), wherein the cooling elements (6) comprise a sinter material and wherein the cooling elements (6) are produced by forming from the material of the base element (4), and wherein the base element (4) has an element height (10) of at most 3 mm, in particular between 1 mm and 2.5 mm.

2. The cooling device (1) according to claim 1, wherein at least one stiffening element (11) is arranged on the base element (4), in particular on the first surface (5).

3. The cooling device (1) according to claim 2, wherein the stiffening element (11) has a rib-shaped configuration.

4. The cooling device (1) according to claim 2, wherein the stiffening element (11) is arranged continuously at the circumference of the base element (4).

5. The cooling device (1) according to claim 2, wherein the stiffening element (11) is arranged between the cooling elements (6).

6. The cooling device (1) according to claim 2, wherein the stiffening element (11) has a wave-shaped configuration.

7. The cooling device (1) according to claim 6, wherein a plurality of wave-shaped stiffening elements (11) forms the cooling elements (6).

8. The cooling device (1) according to claim 2, wherein the stiffening element (11) has a height (16) which corresponds to between 20% and 100% of a maximum height (8) of the cooling elements (6).

9. The cooling device (1) according to claim 2, wherein the stiffening element (11) comprises a sinter material and is produced by forming from the material of the base element (4).

10. The cooling device (1) according to a claim 2, wherein the stiffening element (11) is arranged with a longitudinal extension in the direction of flow for a cooling fluid through the cooling device (1).

11. A method for producing a cooling device (1) comprising the steps of providing a material and forming a cooling structure from the material, wherein a sintering powder is used as the material, from which a green compact is produced by pressing, wherein the green compact is sintered to form a preform (17), and the cooling structure is produced from the preform (17) in the form of cooling elements (6) by forming, for which purpose a part of the preform (6) is pressed through a mold (18), wherein a base element (4) is formed from the preform (17), on which base element the cooling elements (6) are configured, and wherein the base element (4) is produced with an element height (10) of at most 3 mm, in particular between 1 mm and 2.5 mm.

12. The method according to claim 11, wherein at least one stiffening element (11) is configured on the base element (4) with the forming of the preform (17).

13. The method according to claim 12, wherein the stiffening element (11) has a rib-shaped configuration.

14. The method according to claim 12, wherein the stiffening element (11) has a wave-shaped configuration.
